(19) United States
(12) Patent Application Publication
(10) Pub. No.: US 2024/0313525 A1
(43) Pub. Date: Sep. 19, 2024

(54) ELECTRONIC APPARATUS WITH SURGE VOLTAGE PROTECTION FUNCTION

(71) Applicant: CABLE VISION ELECTRONICS CO., LTD., New Taipei City (TW)

(72) Inventors: Chien-Chung LEE, New Taipei City (TW); Min-Chi TSENG, New Taipei City (TW); Cheng-Wei PENG, New Taipei City (TW); Yu-An CHEN, New Taipei City (TW)

(21) Appl. No.: 18/198,137

(22) Filed: May 16, 2023

(30) Foreign Application Priority Data
Mar. 16, 2023 (TW) 112202352

(51) Int. Cl. H02H 9/04; H05K 1/16

(52) U.S. Cl. CPC H02H 9/044; H05K 1/165; H05K 1/167; H05K 2201/095; H05K 2201/10666

(57) ABSTRACT

An electronic apparatus includes a printed circuit board, a terminal and a surge voltage protection structure. The printed circuit board includes a first plated through hole, a second plated through hole and a ground terminal. The surge voltage protection structure includes the first plated through hole and the second plated through hole. The first plated through hole is electrically connected to the terminal. The second plated through hole is connected to the ground terminal. A gap is defined between the first plated through hole and the second plated through hole. The first plated through hole receives a surge voltage to generate an electric arc across the gap and transmit the electric arc through the gap to the second plated through hole, so that the second plated through hole receives the electric arc to transfer an energy of the electric arc to the ground terminal.

### BACKGROUND OF THE DISCLOSURE

### Technical Field

The present disclosure relates to an electronic apparatus, and especially relates to an electronic apparatus with a surge voltage protection function.

### Description of Related Art

A surge voltage, such as the surge voltage caused by a lightning stroke, may enter and exit an electronic apparatus through an input terminal and an output terminal of the electronic apparatus and may damage components in the electronic apparatus. Currently, in order to prevent the surge voltage from damaging the components in the electronic apparatus, the electronic apparatus is equipped with a general surge voltage protection component, such as a varistor. However, a price of the general surge voltage protection component is high (especially the price of a better surge voltage protection component is higher), so that an arrangement of the general surge voltage protection component greatly increases a cost of the components.

### SUMMARY OF THE DISCLOSURE

In order to solve the above-mentioned problems, an object of the present disclosure is to provide an electronic apparatus with a surge voltage protection function.

In order to achieve the object of the present disclosure mentioned above, the electronic apparatus with the surge voltage protection function of the present disclosure includes a printed circuit board, a terminal and a surge voltage protection structure. The printed circuit board includes a first plated through hole, a second plated through hole and a ground terminal. The terminal is arranged on the printed circuit board. Moreover, the surge voltage protection structure includes the first plated through hole and the second plated through hole. The first plated through hole is electrically connected to the terminal. The second plated through hole is connected to the ground terminal. Moreover, a gap is defined (namely, there is a gap) between the first plated through hole and the second plated through hole. The first plated through hole is configured to receive a surge voltage to generate an electric arc across the gap and transmit the electric arc through the gap to the second plated through hole, so that the second plated through hole is configured to receive the electric arc to transfer an energy of the electric arc to the ground terminal. Moreover, in an embodiment of the electronic apparatus with the surge voltage protection function of the present disclosure mentioned above, the gap is between 0.2 millimeter and 1 millimeter.

Moreover, in an embodiment of the electronic apparatus with the surge voltage protection function of the present disclosure mentioned above, the surge voltage protection structure further includes a first metal column. The first metal column is filled in the first plated through hole and is electrically connected to the first plated through hole and the terminal.

Moreover, in an embodiment of the electronic apparatus with the surge voltage protection function of the present disclosure mentioned above, the surge voltage protection structure further includes a second metal column. The second metal column is filled in the second plated through hole and is electrically connected to the second plated through hole and the ground terminal.

Moreover, in an embodiment of the electronic apparatus with the surge voltage protection function of the present disclosure mentioned above, the first metal column is a tin column. The second metal column is a tin column.

Moreover, in an embodiment of the electronic apparatus with the surge voltage protection function of the present disclosure mentioned above, the surge voltage protection structure further includes an inductor and a resistor. The inductor is arranged on the printed circuit board and is electrically connected to the terminal, the first plated through hole and the first metal column. The resistor is arranged on the printed circuit board and is electrically connected to the terminal, the first plated through hole, the first metal column and the inductor.

Moreover, in an embodiment of the electronic apparatus with the surge voltage protection function of the present disclosure mentioned above, the electronic apparatus with the surge voltage protection function further includes a choke, an input terminal capacitor, an output terminal capacitor, a coupler and a splitter. The choke is arranged on the printed circuit board and is electrically connected to the terminal. The input terminal capacitor is arranged on the printed circuit board and is electrically connected to the choke. The output terminal capacitor is arranged on the printed circuit board and is electrically connected to the choke. The coupler is arranged on the printed circuit board and is electrically connected to the input terminal capacitor and the output terminal capacitor. The splitter is arranged on the printed circuit board and is electrically connected to the coupler. Moreover, the terminal is a cable television signal input terminal, a cable television signal output terminal or a cable television signal splitter output terminal.

Moreover, in an embodiment of the electronic apparatus with the surge voltage protection function of the present disclosure mentioned above, the second plated through hole is non-circular.

Moreover, in an embodiment of the electronic apparatus with the surge voltage protection function of the present disclosure mentioned above, the first plated through hole is oval. The second plated through hole is oval.

Moreover, in an embodiment of the electronic apparatus with the surge voltage protection function of the present disclosure mentioned above, the first plated through hole is circular. The second plated through hole is arc-shaped partially surrounding the first plated through hole.

The advantage of the present disclosure is to protect the electronic apparatus from the damage caused by the surge voltage without the need for the general and the expensive surge voltage protection component.

Please refer to the detailed descriptions and figures of the present disclosure mentioned below for further understanding the technology, method and effect of the present disclosure achieving the predetermined purposes. It believes that the purposes, characteristic and features of the present disclosure can be understood deeply and specifically. However, the figures are only for references and descriptions, but the present disclosure is not limited by the figures.

### BRIEF DESCRIPTION OF THE DRAWINGS

FIG. 1 shows a partial schematic diagram of the electronic apparatus with the surge voltage protection function of the present disclosure.

FIG. 2 shows a circuit block diagram of the electronic apparatus with the surge voltage protection function of the present disclosure.

FIG. 3 shows a schematic diagram of another embodiment of the shape of the second plated through hole and the shape of the first plated through hole of the present disclosure.

FIG. 4 shows a schematic diagram of still another embodiment of the shape of the second plated through hole and the shape of the first plated through hole of the present disclosure.

### DETAILED DESCRIPTION

In the present disclosure, numerous specific details are provided, to provide a thorough understanding of embodiments of the disclosure. Persons of ordinary skill in the art will recognize, however, that the present disclosure can be practiced without one or more of the specific details. In other instances, well-known details are not shown or described to avoid obscuring aspects of the present disclosure. Now please refer to the figures for the explanation of the technical content and the detailed description of the present disclosure:

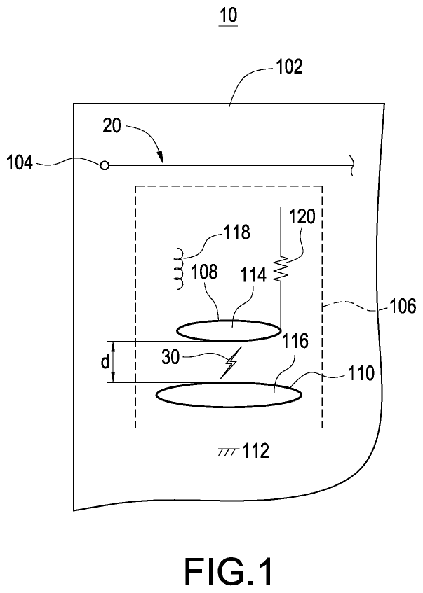

FIG. 1 shows a partial schematic diagram of the electronic apparatus 10 with the surge voltage protection function of the present disclosure. The electronic apparatus 10 with the surge voltage protection function of the present disclosure includes a printed circuit board 102, a terminal 104 and a surge voltage protection structure 106. The printed circuit board 102 includes a first plated through hole 108, a second plated through hole 110 and a ground terminal 112. The surge voltage protection structure 106 includes the first plated through hole 108, the second plated through hole 110, a first metal column 114, a second metal column 116, an inductor 118 and a resistor 120. A gap d is defined (namely, there is a gap d) between the first plated through hole 108 and the second plated through hole 110.

The terminal 104, the inductor 118 and the resistor 120 are arranged on the printed circuit board 102. The first metal column 114 is a tin column. The first metal column 114 is filled in the first plated through hole 108 by, for example, the soldering technology. The second metal column 116 is a tin column. The second metal column 116 is filled in the second plated through hole 110 by, for example, the soldering technology. The resistor 120, the terminal 104, the first plated through hole 108, the first metal column 114 and the inductor 118 are electrically connected to each other. The second metal column 116, the second plated through hole 110 and the ground terminal 112 are electrically connected to each other.

For example, a surge voltage 20 caused by a lightning stroke may enter and exit the electronic apparatus 10 with the surge voltage protection function through the terminal 104. When the surge voltage 20 is generated, the first plated through hole 108 is configured to receive the surge voltage to generate an electric arc 30 across the gap d and transmit the electric arc 30 through the gap d to the second plated through hole 110 (namely, when the surge voltage 20 passes through the inductor 118 and the gap d, the electric arc 30 is generated across/in the gap d), so that the second plated through hole 110 is configured to receive the electric arc 30 to transfer an energy of the electric arc 30 to the ground terminal 112, whereby the electronic apparatus 10 with the surge voltage protection function can be protected from the damage caused by the surge voltage 20.

For the present disclosure, the gap d is extremely important. If the gap d is too small, then the first plated through hole 108 and the second plated through hole 110 are easily short-circuited. If the gap d is too large, the electric arc 30 is not easily generated across/in the gap d. After careful researches and experiments by the inventors of the present disclosure, it is found that the effect of the gap d being between 0.2 millimeter and 1 millimeter is the best, which can make the first plated through hole 108 and the second plated through hole 108 are not prone to be short-circuited but can generate the electric arc 30 across/in the gap d.

Moreover, the first plated through hole 108 and the first metal column 114 are configured to receive the surge voltage 20 to generate the electric arc 30 across/in the gap d and transmit the electric arc 30 through the gap d to the second plated through hole 110 and the second metal column 116, so that the second plated through hole 110 and the second metal column 116 are configured to receive the electric arc 30 to transfer the energy of the electric arc 30 to the ground terminal 112. The inductor 118 is connected to the resistor 120 in parallel. The inductor 118 is configured to receive the surge voltage 20 to transfer the surge voltage 20 to the first plated through hole 108 and the first metal column 114. The resistor 120 is configured to reduce a resonant Q value of the inductor 118 to prevent notching at a particular frequency.

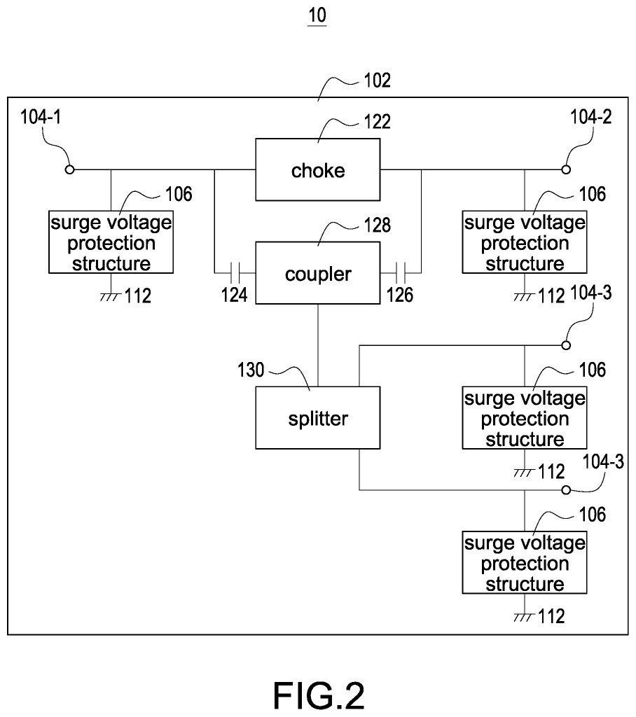

FIG. 2 shows a circuit block diagram of the electronic apparatus 10 with the surge voltage protection function of the present disclosure. The descriptions of the elements shown in FIG. 2 which are the same as the elements shown in FIG. 1 are not repeated here for brevity. The electronic apparatus 10 with the surge voltage protection function further includes a choke 122, an input terminal capacitor 124, an output terminal capacitor 126, a coupler 128 and a splitter 130. The terminal 104 shown in FIG. 1 is a cable television signal input terminal 104-1, a cable television signal output terminal 104-2 or a cable television signal splitter output terminal 104-3. FIG. 2 includes the cable television signal input terminal 104-1, the cable television signal output terminal 104-2 and a plurality of the cable television signal splitter output terminals 104-3. The components mentioned above are electrically connected to each other and are arranged on the printed circuit board 102. Moreover, the cable television signal input terminal 104-1 and the cable television signal output terminal 104-2 are connected to a main line (not shown in FIG. 2) of the cable television (CATV). The cable television signal splitter output terminals 104-3 are respectively connected to user sides (not shown in FIG. 2).

Moreover, the input terminal capacitor 124 and the output terminal capacitor 126 are capacitors with high voltage endurance. When the surge voltage 20 is lower than a predetermined voltage (for example, 2000 volts), the input terminal capacitor 124 and the output terminal capacitor 126 are configured to block the surge voltage 20.

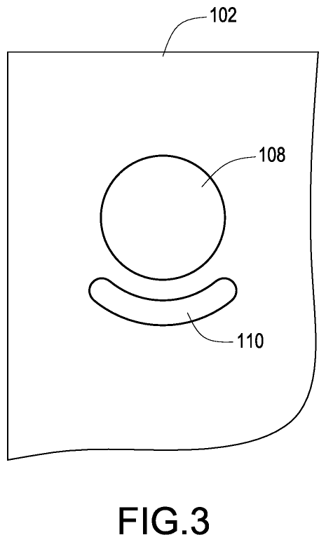

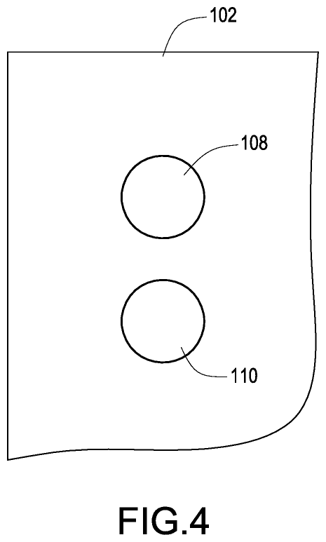

Please refer to FIG. 1 again. The second plated through hole 110 is non-circular or circular. For example, as shown in FIG. 1, the second plated through hole 110 is oval, and the first plated through hole 108 is oval. However, the present disclosure does not limit a shape of the second plated through hole 110 and a shape of the first plated through hole 108. FIG. 3 shows a schematic diagram of another embodiment of the shape of the second plated through hole 110 and the shape of the first plated through hole 108 of the present disclosure. As shown in FIG. 3, the first plated through hole 108 is circular, and the second plated through hole 110 is arc-shaped partially surrounding the first plated through hole 108. FIG. 4 shows a schematic diagram of still another embodiment of the shape of the second plated through hole 110 and the shape of the first plated through hole 108 of the present disclosure. As shown in FIG. 4, the first plated through hole 108 is circular, and the second plated through hole 110 is also circular.

The advantage of the present disclosure is to protect the electronic apparatus from the damage caused by the surge voltage without the need for the general and the expensive surge voltage protection component.

Although the present disclosure has been described with reference to the embodiment thereof, it will be understood that the disclosure is not limited to the details thereof. Various substitutions and modifications have been suggested in the foregoing description, and others will occur to those of ordinary skill in the art. Therefore, all such substitutions and modifications are intended to be embraced within the scope of the disclosure as defined in the appended claims.

What is claimed is:

1. An electronic apparatus with a surge voltage protection function comprising:
a printed circuit board comprising a first plated through hole, a second plated through hole and a ground terminal;
a terminal arranged on the printed circuit board; and
a surge voltage protection structure,
wherein the surge voltage protection structure comprises:
the first plated through hole electrically connected to the terminal; and
the second plated through hole connected to the ground terminal,
wherein a gap is defined between the first plated through hole and the second plated through hole; the first plated through hole is configured to receive a surge voltage to generate an electric arc across the gap and transmit the electric arc through the gap to the second plated through hole, so that the second plated through hole is configured to receive the electric arc to transfer an energy of the electric arc to the ground terminal.

2. The electronic apparatus with the surge voltage protection function of claim 1, wherein the gap is between 0.2 millimeter and 1 millimeter.

3. The electronic apparatus with the surge voltage protection function of claim 1, wherein the surge voltage protection structure further comprises:
a first metal column filled in the first plated through hole and electrically connected to the first plated through hole and the terminal.

4. The electronic apparatus with the surge voltage protection function of claim 3, wherein the surge voltage protection structure further comprises:
a second metal column filled in the second plated through hole and electrically connected to the second plated through hole and the ground terminal.

5. The electronic apparatus with the surge voltage protection function of claim 4, wherein the first metal column is a tin column; the second metal column is a tin column.

6. The electronic apparatus with the surge voltage protection function of claim 4, wherein the surge voltage protection structure further comprises:
an inductor arranged on the printed circuit board and electrically connected to the terminal, the first plated through hole and the first metal column; and
a resistor arranged on the printed circuit board and electrically connected to the terminal, the first plated through hole, the first metal column and the inductor.

7. The electronic apparatus with the surge voltage protection function of claim 6, further comprising:
a choke arranged on the printed circuit board and electrically connected to the terminal;
an input terminal capacitor arranged on the printed circuit board and electrically connected to the choke;
an output terminal capacitor arranged on the printed circuit board and electrically connected to the choke;
a coupler arranged on the printed circuit board and electrically connected to the input terminal capacitor and the output terminal capacitor; and
a splitter arranged on the printed circuit board and electrically connected to the coupler,
wherein the terminal is a cable television signal input terminal, a cable television signal output terminal or a cable television signal splitter output terminal.

8. The electronic apparatus with the surge voltage protection function of claim 1, wherein the second plated through hole is non-circular.

9. The electronic apparatus with the surge voltage protection function of claim 8, wherein the first plated through hole is oval; the second plated through hole is oval.

10. The electronic apparatus with the surge voltage protection function of claim 8, wherein the first plated through hole is circular; the second plated through hole is arc-shaped partially surrounding the first plated through hole.
